(19) United States
(12) Patent Application Publication
(10) Pub. No.: US 2026/0353580 A1
(43) Pub. Date: Nov. 5, 2026

(54) ELECTRONIC LOCK HOUSING SEALING STRUCTURE AND ELECTRONIC LOCK

(71) Applicant: TAIWAN FU HSING INDUSTRIAL CO., LTD., Kaohsiung City (TW)

(72) Inventor: Meng-Ping Syu, Kaohsiung City (TW)

(73) Assignee: TAIWAN FU HSING INDUSTRIAL CO., LTD., Kaohsiung City (TW)

(21) Appl. No.: 19/059,300

(22) Filed: Feb. 21, 2025

(30) Foreign Application Priority Data
Jan. 10, 2025 (TW) 114200374

(51) Int. Cl. H05K 5/06; G07C 9/00

(52) U.S. Cl. CPC H05K 5/061; G07C 9/00944; H05K 5/069

(57) ABSTRACT

An electronic lock housing sealing structure includes a supporting frame, a waterproof gasket, a separation plate, and a holding plate. The waterproof gasket and the separation plate are located on opposite sides of the supporting frame in a direction. The separation plate contacts the waterproof gasket through an opening portion of the supporting frame, so as to form an electronic component accommodating space together with the waterproof gasket. The holding plate is located beside the waterproof gasket so that the waterproof gasket is located between the separation plate and the holding plate. The holding plate and the separation plate are connected through a connection hole of the waterproof gasket to make the waterproof gasket fit tightly against the separation plate. An electronic lock includes the above electronic lock housing sealing structure, and a printed circuit board accommodated in the electronic component accommodating space.

### BACKGROUND OF THE INVENTION

### 1. Field of the Invention

The present invention relates to an electronic lock housing sealing structure and an electronic lock with waterproof effect.

### 2. Description of the Prior Art

Sometimes electronic locks are installed on door panels that are exposed to the outdoors. If the electronic lock is not waterproof, rain or moisture can easily enter the interior of the electronic lock, causing problems such as short circuit of electronic components and circuit corrosion. Although some electronic locks are equipped with waterproof gaskets, the waterproof gaskets often warp during the installation of the electronic locks, thereby reducing the waterproof function of the waterproof gasket or even making it ineffective.

### SUMMARY OF THE INVENTION

In view of the problems in the prior art, an objective of the invention is to provide an electronic lock housing sealing structure, whose waterproof gasket is firmly fixed in the structure before the electronic lock housing sealing structure is installed on a door panel, so that the waterproof function of the waterproof gasket will not be affected by the installation.

An electronic lock housing sealing structure of an embodiment according to the invention includes a supporting frame, a waterproof gasket, a separation plate, and a holding plate. The supporting frame has an opening portion passing through the supporting frame in a direction. The waterproof gasket is located on an inner side of the supporting frame in the direction, and has a connection hole. The separation plate is located on an outer side of the supporting frame in the direction. The separation plate contacts the waterproof gasket through the opening portion, so as to form an electronic component accommodating space together with the waterproof gasket. The holding plate is located on the inner side of the supporting frame in the direction. The waterproof gasket is located between the separation plate and the holding plate. The holding plate and the separation plate are connected to each other through the connection hole so that the waterproof gasket fits tightly against the separation plate. Thereby, the waterproof gasket is firmly sandwiched between the separation plate and the holding plate, so the subsequent installation will not change the connection relationship between the waterproof gasket and the separation plate and affect the waterproof effect to the electronic component accommodating space.

Another objective of the invention is to provide an electronic lock, which includes an electronic lock housing sealing structure and a printed circuit board. The electronic lock housing sealing structure includes a supporting frame, a waterproof gasket, a separation plate, and a holding plate. The supporting frame has an opening portion passing through the supporting frame in a direction. The waterproof gasket is located on an inner side of the supporting frame in the direction, and has a connection hole. The separation plate is located on an outer side of the supporting frame in the direction. The separation plate contacts the waterproof gasket through the opening portion, so as to form an electronic component accommodating space together with the waterproof gasket. The holding plate is located on the inner side of the supporting frame in the direction. The waterproof gasket is located between the separation plate and the holding plate. The holding plate and the separation plate are connected to each other through the connection hole so that the waterproof gasket fits tightly against the separation plate. The printed circuit board is disposed in the electronic component accommodating space of the electronic lock housing sealing structure. Similarly, the waterproof gasket is firmly sandwiched between the separation plate and the holding plate, so the subsequent installation of the electronic lock will not change the connection relationship between the waterproof gasket and the separation plate and affect the waterproof effect to the electronic component accommodating space, thereby ensuring that the printed circuit board obtains an expected waterproof effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an electric lock according to an embodiment.

FIG. 2 is a schematic diagram of the electric lock in FIG. 1 in another viewpoint.

FIG. 3 is an exploded view of the electric lock in FIG. 1.

FIG. 4 is another exploded view of the electric lock in FIG. 3 in another viewpoint.

FIG. 5 is a sectional view of the electric lock along the line X-X in FIG. 1.

FIG. 6 is a sectional view of the electric lock along the line Y-Y in FIG. 2.

FIG. 7 is a schematic diagram illustrating a portion of the combination of a separation plate and a waterproof gasket of the electronic lock in FIG. 3.

FIG. 8 is a front view of the rear side of the separation plate.

### DETAILED DESCRIPTION

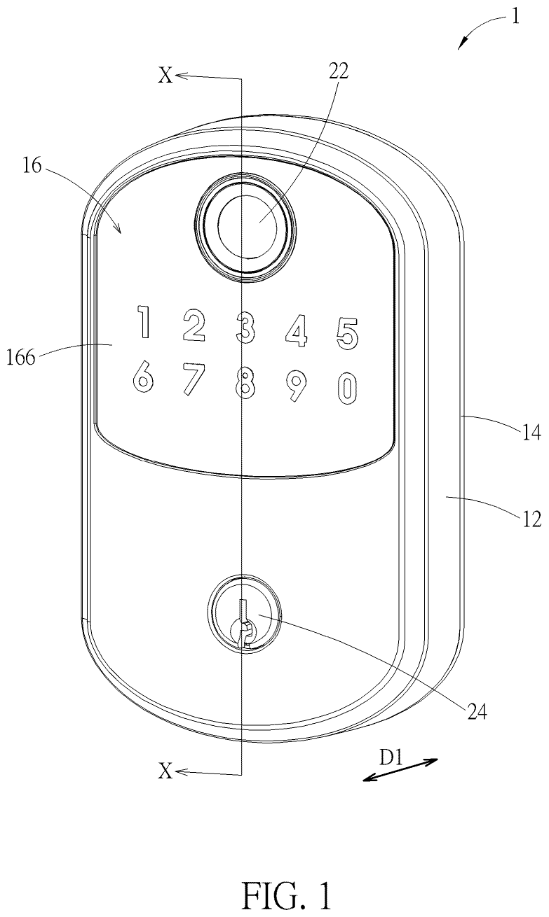

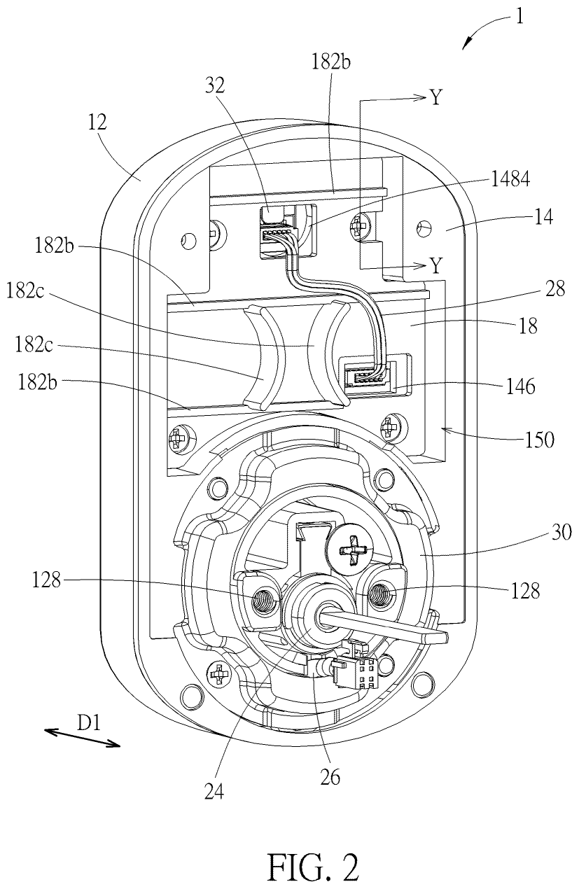

Please refer to FIG. 1 to FIG. 4. An electric lock 1 according to an embodiment can be installed onto an outer side of a door panel, and includes a supporting frame 12, a waterproof gasket 14, a membrane switch assembly 16, a holding plate 18, a switch circuit board assembly 20, a fingerprint identification component 22, and a lock cylinder 24. In a direction D1 (indicated by a doubled-headed arrow in FIG. 1 and FIG. 2), the membrane switch assembly 16, the supporting frame 12, the waterproof gasket 14, and the holding plate 18 are arranged in sequence and combined together. The switch circuit board assembly 20 is accommodated between the membrane switch assembly 16 and the waterproof gasket 14 and is connected to the outside through a cable 26 (which may include connectors at ends of the cable 26) (for example, connected to a control assembly disposed on the inner side of the door panel through a mounting hole on the door panel). The membrane switch assembly 16 is exposed from the electronic lock 1 and can be operated to trigger the switch circuit board assembly 20. The fingerprint identification component 22 is accommodated on the membrane switch assembly 16 and the holding plate 18 and is connected to the switch circuit board assembly 20 through a cable 28 (which may include connectors at ends of the cable 28). The fingerprint identification component 22 is exposed from the electronic lock 1 and is used for identifying fingerprints. The lock cylinder 24 is fixed on the supporting frame 12. The latch driving rod of the lock cylinder 24 is used to drive a latch of a latch assembly (not shown in the figures) disposed on the door panel. The electronic lock 1 is installed on the door panel through the supporting frame 12. Furthermore, the electronic lock 1 also includes an auxiliary base plate 30, which is fixed on the supporting frame 12 and fits in the mounting hole of the door panel during installation. On the other hand, the combination of the supporting frame 12, the waterproof gasket 14, the membrane switch assembly 16, and the holding plate 18 can be logically taken as an electronic lock housing sealing structure, providing a waterproof effect for the switch circuit board assembly 20.

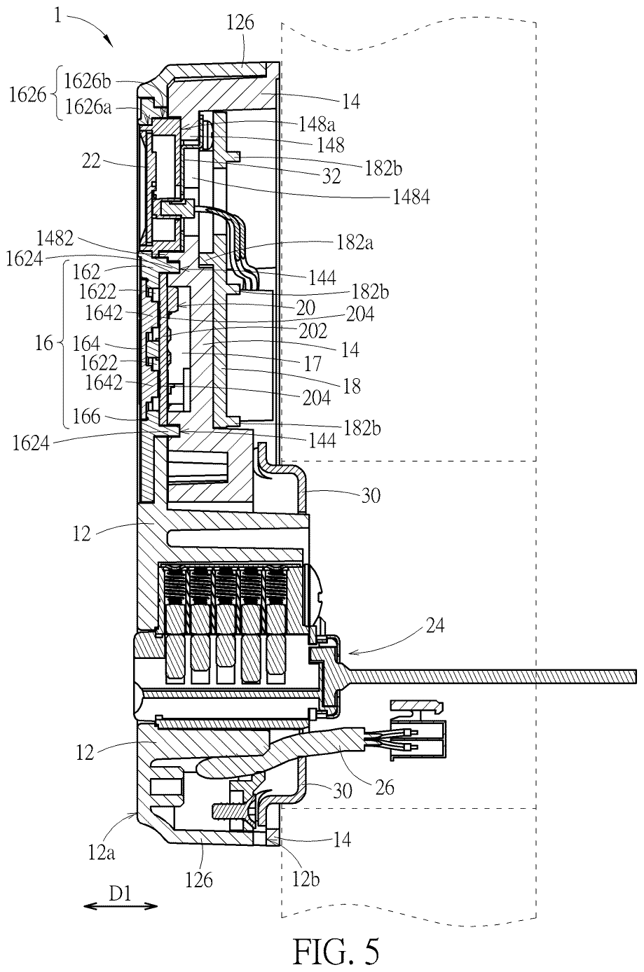

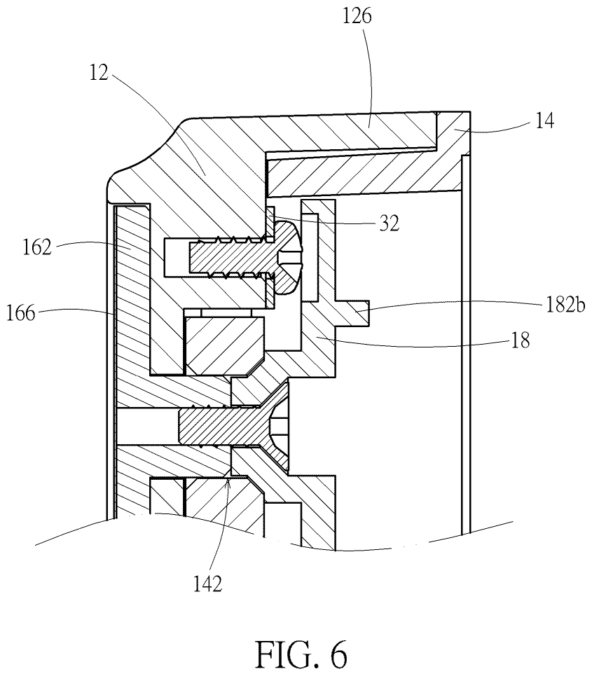

Please also refer to FIG. 5 and FIG. 6; therein, the door panel is shown in dashed lines in FIG. 5. Further, in the embodiment, the supporting frame 12 has a first opening portion 122 and a second opening portion 124, both of which pass through the supporting frame 12 in the direction D1. A printed circuit board 202 of the switch circuit board assembly 20 has a plurality of switches 204 (e.g., but not limited to, pairs of contacts) arranged toward the first opening portion 122. The membrane switch assembly 16 includes a separation plate 162, a flexible pad 164 (e.g., but not limited to, a rubber pad), and a membrane 166. The waterproof gasket 14 and the separation plate 162 are located on an inner side 12a and an outer side 12b in the direction D1, respectively. The separation plate 162 has a plurality of operation holes 1622, which are aligned with the plurality of switches 204. The flexible pad 164 is attached to the separation plate 162 and covers the plurality of operation holes 1622. A plurality of protrusions 1642 on the flexible pad 164 extend into the plurality of operation holes 1622 correspondingly. The membrane 166 is attached to an outer surface of the flexible pad 164. The membrane 166 has symbols formed thereon corresponding to the protrusions 1642 (i.e., corresponding to the switches 204). A user can press the membrane 166 toward one of the symbols to move the corresponding protrusion 1642 toward the printed circuit board 202 to trigger the corresponding switch 204.

The separation plate 162 contacts the waterproof gasket 14 through the first opening portion 122, so that the separation plate 162 and the waterproof gasket 14 jointly form an electronic component accommodating space 17 (referring to FIG. 5). The plurality of operation holes 1622 are connected to the electronic component accommodating space 17. At least the printed circuit board 202 of the switch circuit board assembly 20 is completely accommodated in the electronic component accommodating space 17. The waterproof gasket 14 has a plurality of connection holes 142.

The holding plate 18 and the separation plate 162 are connected to each other through the plurality of connection holes 142 (for example, both form bosses with holes, and the bosses extend into the connection holes 142 to directly abut against each other and be fixed with screws, as shown by FIG. 6; the supporting frame 12 correspondingly forms an avoidance structure for the bosses to pass through), so that the holding plate 18 and the separation plate 162 sandwich the waterproof gasket 14 to make the waterproof gasket 14 fit tightly against the separation plate 162. Therein, the waterproof gasket 14 includes a groove 144. The separation plate 162 correspondingly includes a protruding wall 1624. The protruding wall 1624 is inserted into the groove 144. The groove 144 and the protruding wall 1624 both surround the electronic component accommodating space 17 to enhance the waterproof effect of the electronic component accommodating space 17. Furthermore, the waterproof gasket 14 and the separation plate 162 also clamp the edges of the printed circuit board 202. In addition, in practice, the flexible pad 164 can be closely attached to the separation plate 162 to effectively seal the plurality of operation holes 1622, thereby effectively preventing moisture from entering the electronic component accommodating space 17 through the plurality of operation holes 1622.

Furthermore, in the embodiment, the groove 144 and the protruding wall 1624 do not completely surround the electronic component accommodating space 17, but have gaps (therein, a gap 1624a of the protruding wall 1624 and a gap 145 of the waterproof gasket 14 form a channel connected to the electronic component accommodating space 17 for the cable 26 to pass through). The gaps are substantially filled with the cable 26, and also help to prevent moisture from entering the electronic component accommodating space 17 therefrom. However, it is not limited thereto in practice. For example, the groove 144 and the protruding wall 1624 completely surround the electronic component accommodating space 17, and the cable 26 enters the electronic component accommodating space 17 through other channels. Furthermore, in practice, a portion of the protruding wall 1624 still remains at the gap 1624a and can press against the cable 26, thereby facilitating the fixing of the cable 26. Moreover, the plurality of connection holes 142 are substantially located around the electronic component accommodating space 17, which helps the holding plate 18 and the separation plate 162 to provide uniform structural restraint to the portion of the waterproof gasket 14 corresponding to the electronic component accommodating space 17. In addition, in practice, the groove 144 can be changed to be disposed on the separation plate 162, and the protruding wall 1624 can be correspondingly changed to be disposed on the waterproof gasket 14; this structural configuration can also achieve the aforementioned waterproof effect.

Furthermore, in practice, the holding plate 18 and the separation plate 162 are hard components, and the waterproof gasket 14 is a soft component (e.g., but not limited to rubber). Therefore, the holding plate 18 and the separation plate 162 can squeeze the waterproof gasket 14 and can maintain relative positions after being directly fixedly connected to each other, so that during the process of installing the electronic lock 1 to the door panel, the squeezing (or clamping) state of the holding plate 18 and the separation plate 162 on the waterproof gasket 14 does not change, thereby making the waterproof effect of the waterproof gasket 14 on the electronic component accommodating space 17 not be affected. In addition, in the embodiment, the waterproof gasket 14 also has an opening 146 connected to the electronic component accommodating space 17 for the cable 28 to pass through.

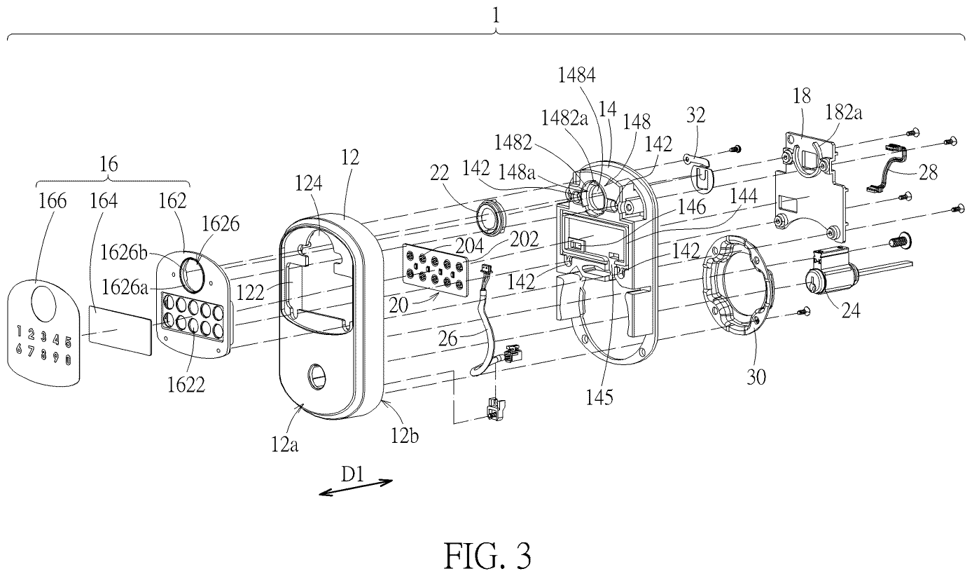

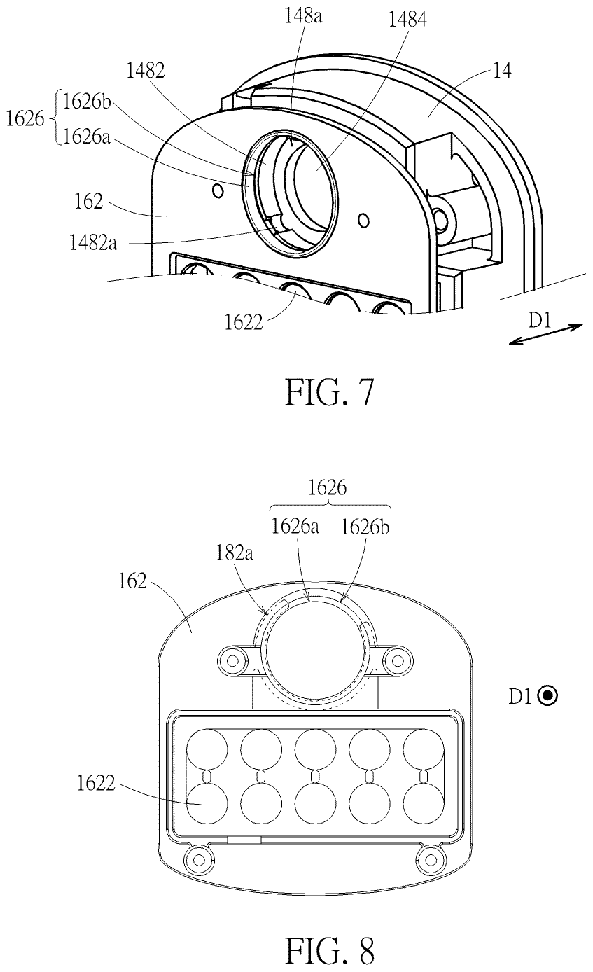

Please refer to FIG. 3 to FIG. 5 and FIG. 7. In the embodiment, the separation plate 162 has an accommodating through hole 1626. The waterproof gasket 14 includes a recess structure 148. The recess structure 148 forms an accommodating area 148a. The separation plate 162 and the recess structure 148 are connected to each other through the second opening portion 124, so that the accommodating through hole 1626 communicates with the accommodating area 148a. The fingerprint identification component 22 is accommodated in the accommodating through hole 1626 and the accommodating area 148a. Therein, the accommodating through hole 1626 has a first portion 1626a and a second portion 1626b, which are arranged in the direction D1 and connected to each other. A cross-section of the second portion 1626b is larger than a cross-section of the first portion 1626a. The recess structure 148 has a protruding wall structure 1482. The protruding wall structure 1482 is formed by three arc-shaped plates, which are arranged in a ring-shaped manner at intervals, in which a positioning notch 1482a is formed between adjacent arc-shaped plates. The separation plate 162 is connected to the recess structure 148 through its second portion 1626b. The protruding wall structure 1482 extends along the direction D1 and is inserted into the second portion 1626b. The fingerprint identification component 22 also fits in the positioning notches 1482a. Furthermore, the bottom of the recess structure 148 has an opening 1484 for the cable 28 to pass through. In addition, the fingerprint identification component 22 is also fixedly connected to the supporting frame 12 through a fixing bracket 32 (e.g., the fixing bracket 32 is fastened with screws).

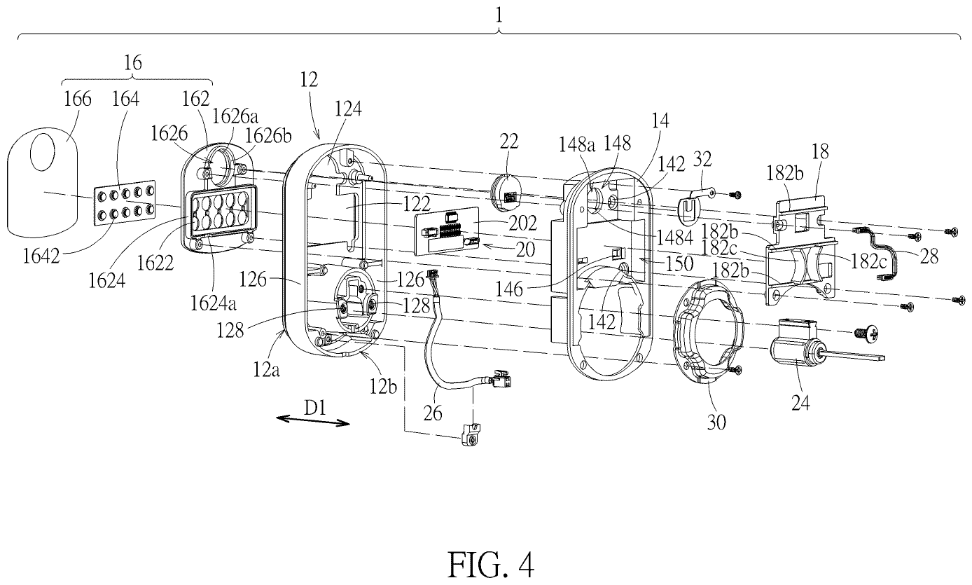

As shown by FIG. 3 and FIG. 4, in the embodiment, the holding plate 18 has a plurality of protruding ribs (including a protruding rib 182a located at the front side (i.e., the side toward the waterproof gasket 14) and extending in an arc shape, three protruding ribs 182b located at the rear side and extending horizontally, and two protruding ribs 182c located at the rear side and extending in an arc shape), which have the effect of strengthening the structure of the holding plate 18 itself. Therein, the protruding rib 182a is tightly against the waterproof gasket 14 toward the recess structure 148, and (also referring to FIG. 8) the protruding rib 182a (the relative position of the outline of which is shown in dashed lines in FIG. 8) overlaps an edge of the second portion 1626b of the accommodating through hole 1626 in the direction D1. This structural configuration is conducive to the structural stability of the connection between the connection between the recess structure 148 and the accommodating through hole 1626. Moreover, (also referring to FIG. 2 and FIG. 5) the protruding ribs 182c are disposed toward the electronic component accommodating space 17. The holding plate 18 is closely attached to the waterproof gasket 14 (corresponding to the portion of the electronic component accommodating space 17) with its flat plate portion. The above two structural configuration features can both enhance the supporting effect provided by the holding plate 18 to the electronic component accommodating space 17.

Furthermore, as shown by FIG. 2 and FIG. 4, in the embodiment, the waterproof gasket 14 has an accommodating recess 150. The holding plate 18 is accommodated in the accommodating recess 150 (as shown by FIG. 2). The outline of the accommodating recess 150 matches the outline of the holding plate 18, which facilitate the pressing of the supporting plate 18 to the waterproof pad 14. Please refer to FIG. 5. The supporting frame 12 has a peripheral wall 126 and two door panel fixing holes 128. The door panel fixing hole 128 is located on an inner side of the peripheral wall 126. The waterproof gasket 14 is against an edge of the peripheral wall 126 in the direction D1. The supporting frame 12 is fixed to the door panel through the door panel fixing hole 128 (for example, by using screws (not shown in the figures) to be screwed into the door panel fixing hole 128 from the inner side of the door panel). Therein, the waterproof gasket 14 is sandwiched between the peripheral wall 126 of the supporting frame 12 and the door panel. The supporting frame 12 does not contact the door panel, so the waterproof gasket 14 can prevent external rain or moisture from entering the electronic lock 1 from between the peripheral wall 126 and the door panel. Furthermore, during the process of installing the electronic lock 1 to the door panel, even if the waterproof gasket 14 is not properly sandwiched between the peripheral wall 126 of the supporting frame 12 and the door panel (e.g., the waterproof gasket 14 cannot be completely and flatly attached to the door panel, causing slight warping around the waterproof gasket 14), the waterproof effect of the waterproof gasket 14 on the electronic component accommodating space 17 will not be affected. In addition, the supporting frame 12 is provided with a plurality of positioning columns to provide positioning of the waterproof gasket 14 relative to the supporting frame 12 (through the positioning columns inserted into corresponding positioning holes on the waterproof gasket 14), which helps to suppress the chance of the waterproof gasket 14 being warped during the installation of the electronic lock 1. The above positioning structure is also implemented in the positioning between the supporting frame 12 and the auxiliary base plate 30, which will not be described in detail.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic lock housing sealing structure, comprising:
a supporting frame, the supporting frame having a first opening portion, the first opening portion passing through the supporting frame in a direction;
a waterproof gasket, the waterproof gasket being located on an inner side of the supporting frame in the direction, the waterproof gasket having a connection hole;
a separation plate, the separation plate being located on an outer side of the supporting frame in the direction, the separation plate contacting the waterproof gasket through the first opening portion, so as to form an electronic component accommodating space together with the waterproof gasket; and
a holding plate, the holding plate being located on the inner side of the supporting frame in the direction, the waterproof gasket being located between the separation plate and the holding plate, the holding plate and the separation plate being connected to each other through the connection hole so that the waterproof gasket fits tightly against the separation plate.

2. The electronic lock housing sealing structure according to claim 1, wherein one of the separation plate and the waterproof gasket comprises a protruding wall, the other of the separation plate and the waterproof gasket comprises a groove, the protruding wall is inserted into the groove, and the protruding wall surrounds the electronic component accommodating space.

3. The electronic lock housing sealing structure according to claim 1, wherein the waterproof gasket has an accommodating recess, the holding plate is accommodated in the accommodating recess, and a contour of the accommodating recess matches a contour of the holding plate.

4. The electronic lock housing sealing structure according to claim 1, wherein the supporting frame has a peripheral wall and a door panel fixing hole, the door panel fixing hole is located on inner side of the peripheral wall, and the waterproof gasket is against an edge of the peripheral wall in the direction.

5. The electronic lock housing sealing structure according to claim 1, further comprising a flexible pad, wherein the separation plate has an operation hole connected to the electronic component accommodating space, and the flexible pad is attached to the separation plate and covers the operation hole.

6. The electronic lock housing sealing structure according to claim 1, wherein the supporting frame has a second opening portion, the separation plate has an accommodating through hole, the waterproof gasket comprises a recess structure, the recess structure forms an accommodating area, and the separation plate and the recess structure are connected to each other through the second opening portion so that the accommodating through hole is communicated with the accommodating area.

7. The electronic lock housing sealing structure according to claim 6, wherein the accommodating through hole has a first portion and a second portion connected to each other in the direction, a cross section of the second portion is larger than a cross section of the first portion, the separation plate is connected to the recess structure through the second portion, the recess structure has a protruding wall structure, and the protruding wall structure extends along the direction and is inserted into the second portion.

8. The electronic lock housing sealing structure according to claim 7, wherein the holding plate comprises a protruding rib, the protruding rib is tightly against the waterproof gasket, and the protruding rib and an edge of the second portion opening overlap in the direction.

9. An electronic lock, comprising:
an electronic lock housing sealing structure, the electronic lock housing sealing structure comprising:
a supporting frame, the supporting frame having a first opening portion, the first opening portion passing through the supporting frame in a direction;
a waterproof gasket, the waterproof gasket being located on an inner side of the supporting frame in the direction, the waterproof gasket having a connection hole;
a separation plate, the separation plate being located on an outer side of the supporting frame in the direction, the separation plate contacting the waterproof gasket through the first opening portion, so as to form an electronic component accommodating space together with the waterproof gasket; and
a holding plate, the holding plate being located on the inner side of the supporting frame in the direction, the waterproof gasket being located between the separation plate and the holding plate, the holding plate and the separation plate being connected to each other through the connection hole so that the waterproof gasket fits tightly against the separation plate; and
a printed circuit board, the printed circuit board being disposed in the electronic component accommodating space.

10. The electronic lock according to claim 9, wherein the printed circuit board has a switch, the electronic lock housing sealing structure comprises a flexible pad, the separation plate has an operation hole, the operation hole is connected to the electronic component accommodating space and aligned with the switch, the flexible pad is attached to the separation plate and covers the operation hole, and the flexible pad is operable to be pressed to trigger the switch.

11. The electronic lock according to claim 9, further comprising a fingerprint identification component, wherein the supporting frame has a second opening portion, the separation plate has an accommodating through hole, the waterproof gasket comprises a recess structure, the recess structure forms an accommodating area, the separation plate and the recess structure are connected to each other through the second opening portion so that the accommodating through hole is communicated with the accommodating area, and the fingerprint identification component is accommodated in the accommodating through hole and the accommodating area.

12. The electronic lock according to claim 11, wherein the accommodating through hole has a first portion and a second portion connected to each other in the direction, a cross section of the second portion is larger than a cross section of the first portion, the separation plate is connected to the recess structure through the second portion, the recess structure has a protruding wall structure, the protruding wall structure extends along the direction and is inserted into the second portion, the protruding wall structure has a positioning notch, and the fingerprint identification component fits in the positioning notch.

13. The electronic lock according to claim 12, wherein the holding plate comprises a protruding rib, the protruding rib is tightly against the waterproof gasket, and the protruding rib and an edge of the second portion opening overlap in the direction.

14. The electronic lock according to claim 9, wherein the waterproof gasket and the separation plate clamp the printed circuit board.

15. The electronic lock according to claim 9, further comprising a lock cylinder, wherein the lock cylinder is fixed on the supporting frame.

16. The electronic lock according to claim 9, wherein one of the separation plate and the waterproof gasket comprises a protruding wall, the other of the separation plate and the waterproof gasket comprises a groove, the protruding wall is inserted into the groove, and the protruding wall surrounds the electronic component accommodating space.

17. The electronic lock according to claim 9, wherein the waterproof gasket has an accommodating recess, the holding plate is accommodated in the accommodating recess, and a contour of the accommodating recess matches a contour of the holding plate.

18. The electronic lock according to claim 9, wherein the supporting frame has a peripheral wall and a door panel fixing hole, the door panel fixing hole is located on inner side of the peripheral wall, and the waterproof gasket is against an edge of the peripheral wall in the direction.
